(19) United States
(12) Patent Application Publication
(10) Pub. No.: US 2017/0076790 A1
(43) Pub. Date: Mar. 16, 2017

(54) SEMICONDUCTOR MEMORY DEVICE

(71) Applicants: Kabushiki Kaisha Toshiba, Minato-ku (JP); Toshiba America Electronic Components, Inc., Irvine, CA (US)

(72) Inventors: Takahiko SASAKI, Tokyo (JP); Go SHIKATA, San Jose, CA (US)

(73) Assignees: Kabushiki Kaisha Toshiba, Minato-ku (JP); Toshiba America Electronic Components, Inc., Irvine, CA (US)

(21) Appl. No.: 15/069,335

(22) Filed: Mar. 14, 2016

Related U.S. Application Data
(60) Provisional application No. 62/218,335, filed on Sep. 14, 2015.

(51) Int. Cl. G11C 11/56

(52) U.S. Cl. CPC G11C 11/5642

(57) ABSTRACT

According to one embodiment, a semiconductor memory device includes first and second memory cells, a word line, first and second bit lines, a sense amplifier and a driver. The first and second memory cells have first and second threshold voltages, respectively. The word line is electrically connected to the first and second memory cells. The first and second bit lines are electrically connected to the first and second memory cells, respectively. The driver increases gradually the voltage of the word line. When the voltage of the word line is increased gradually by the driver, the sense amplifier senses the first and second threshold voltages in ascending order.

### CROSS-REFERENCE TO RELATED APPLICATIONS

This application claims the benefit of U.S. Provisional Application No. 62/218,335, filed Sep. 14, 2015, the entire contents of which are incorporated herein by reference.

### FIELD

Embodiments described herein relate generally to a semiconductor memory device.

### BACKGROUND

NAND flash memories are known as semiconductor memory devices.

### BRIEF DESCRIPTION OF THE DRAWINGS

FIG. 1 is a block diagram showing the configuration of a semiconductor memory device according to an embodiment;

FIG. 2 is a diagram showing a data storing method by sequential storage according to the embodiment;

FIG. 3 is a diagram showing a data reading method according to the embodiment;

FIG. 4 is a diagram showing the configurations of a sense amplifier, a row decoder, and a driver according to the embodiment;

FIG. 5 is a circuit diagram of a sense circuit of the sense amplifier according to the embodiment;

FIGS. 6 and 7 are circuit diagrams of a sequential comparison circuit of the sense amplifier according to the embodiment;

FIG. 8 is a circuit diagram of a word line driver according to the embodiment; and

FIG. 9 is a timing chart showing a read operation according to the embodiment.

FIG. 10 is a diagram showing a magnitude relation of threshold voltages of memory cell transistors and a signal output from a sequential comparison circuit.

### DETAILED DESCRIPTION

Hereinafter, an embodiment will be described with reference to the drawings. In the description below, components having the same functions and configurations are denoted by the same reference signs.

In general, according to one embodiment, a semiconductor memory device includes a first memory cell, a second memory cell, a word line, a first bit line, a second bit line, a sense amplifier and a driver. The first memory cell has a first threshold voltage. The second memory cell has a second threshold voltage. The word line is electrically connected to the first and second memory cells. The first bit line is electrically connected to the first memory cell. The second bit line is electrically connected to the second memory cell. The sense amplifier is electrically connected to the first bit line and the second bit line, and senses the first threshold voltage and the second threshold voltage. The driver increases gradually the voltage of the word line. When the voltage of the word line is increased gradually by the driver, the sense amplifier senses the first and second threshold voltages in ascending order.

A semiconductor memory device according to an embodiment is described below. Here, a planar NAND flash memory in which memory cell transistors are two-dimensionally arranged on a semiconductor substrate is described as the semiconductor memory device by way of example.

[Overall Configuration]

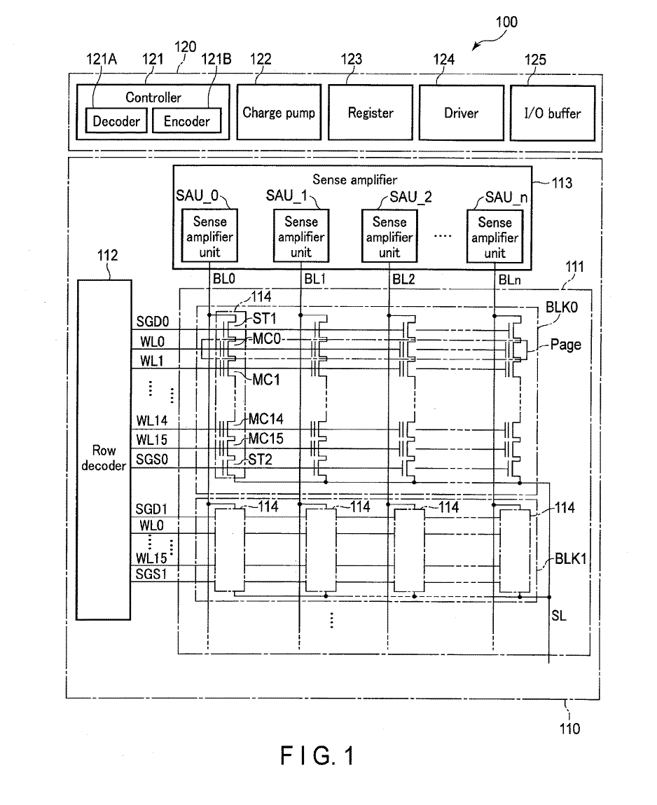

The overall configuration of the semiconductor memory device according to the embodiment is described with reference to FIG. 1. As shown, a NAND flash memory 100 includes a core section 110 and a peripheral circuit 120.

The core section 110 includes a memory cell array 111, a row decoder 112, and a sense amplifier 113.

The memory cell array 111 includes blocks BLK0, BLK1, . . . which are assemblies of nonvolatile memory cell transistors. A block BLK when mentioned in this way hereinafter indicates each of the blocks BLK0, BLK1, . . . . Data in one block BLK are, for example, collectively erased. An erasing range of data is not limited to one block BLK, and more than one block may be collectively erased, or a partial region of one block BLK may be collectively erased.

The block BLK includes NAND strings 114 in which memory cell transistors are connected in series. The memory cell transistors are two-dimensionally arrayed on a semiconductor substrate. Any number of NAND strings 114 may be included in one block.

Each of the NAND strings 114 includes, for example, 16 memory cell transistors MC0, MC1, . . . , and MC15, and select transistors ST1 and ST2. A memory cell transistor MC when mentioned in this way hereinafter indicates each of the memory cell transistors MC0 to MC15.

The memory cell transistor MC includes a stack gate which includes a control gate and a charge storage layer, and saves data in a nonvolatile manner. The memory cell transistor MC may be a metal-oxide-nitride-oxide-silicon (MONOS) type that uses an insulating film as the charge storage layer, or may be a floating gate (FG) type that uses an electrically conductive film as the charge storage layer. Moreover, the number of the memory cell transistors MC is not exclusively 16, and may be, for example, 8, 32, 64, or 128 and is not limited.

The memory cell transistors MC0 to MC15 have their sources or drains connected in series. The drain of the memory cell transistor MC0 at one end of this series connection is connected to the source of the select transistor ST1, and the source of the memory cell transistor MC15 at the other end is connected to the drain of the select transistor ST2.

The gates of the select transistors ST1 in the block BLK are connected in common to the same select gate line. In the example of FIG. 1, the gates of the select transistors ST1 in the block BLK0 are connected in common to the select gate line SGD0, and the gates of the unshown select transistors ST1 in the block BLK1 are connected in common to the select gate line SGD1. Similarly, the gates of the select transistors ST2 in the block BLK0 are connected in common to the select gate line SGS0, and the gates of the unshown select transistors ST2 in the block BLK1 are connected in common to the select gate line SGS1. A select gate line SGD when mentioned in this way hereinafter indicates each of the select gate lines SGD0, SGD1, . . . , and a select gate line SGS when mentioned in this way hereinafter indicates each of the select gate lines SGS0, SGS1, . . . .

The control gates of the memory cell transistors MC of each of the NAND strings 114 in the block BLK are respectively connected in common to the word lines WL0 to WL15. That is, the control gates of the memory cell transistor MC0 of each of the NAND strings 114 are connected in common to the word line WL0. Similarly, the control gates of the memory cell transistors MC1 to MC15 are respectively connected in common to the word lines WL1 to WL15.

The drains of select transistors ST1 of the NAND strings 114 in the same column among the NAND strings 114 arranged in the memory cell array 111 in matrix form are respectively connected in common to the bit lines BL0, BL1, . . . , and BLn (n is a natural number equal to or more than 0). That is, each of the bit lines BL0 to BLn is connected in common to the NAND string 114 in the blocks BLK. A bit line BL when mentioned in this way hereinafter indicates each of the bit lines BL0, BL1, . . . , and BLn.

The sources of the select transistors ST2 in the block BLK are connected in common to the source line SL. That is, the source lines SL are connected in common to the NAND strings 114 in the blocks BLK.

For example, in data writing and reading, the row decoder 112 decodes an address of the block BLK or an address of a page to select a word line corresponding to a page targeted for writing and reading. The row decoder 112 also applies suitable voltages to the selected word line WL, the unselected word lines WL, and the select gate lines SGD and SGS.

The sense amplifier 113 includes sense amplifier units SAU_0, SAU_1, . . . , and SAU_n. Each of the sense amplifier units SAU_0 to SAU_n is provided to correspond to each of the bit lines BL0 to BLn. A sense amplifier unit SAU when mentioned in this way hereinafter indicates each of the sense amplifier units SAU_0 to SAU_n.

In data reading, the sense amplifier unit SAU senses and amplifies data read into the bit line BL from the memory cell transistor MC. In data writing, the sense amplifier unit SAU transfers write data to the memory cell transistor MC. The sense amplifier unit SAU includes a sense section to sense data, and a sequential comparison circuit which compares the sensed data. Details of the sense section and the sequential comparison circuit will be described later.

The peripheral circuit 120 includes a controller 121, a charge pump 122, a register 123, a driver 124, and an input/output buffer 125.

The controller 121 controls the overall operation of the NAND flash memory 100. The controller 121 includes a decoder 121A and an encoder 121B. During a write operation, the decoder 121A decodes write data input from, for example, an external controller, and then generates data to be written into the block BLK. In a read operation, the encoder 121B encodes data read from the block BLK, and outputs the encoded data to the external controller via the input/output buffer 125.

The charge pump 122 generates voltages necessary for data writing, reading, and erasing, and supplies the voltages to the driver 124.

The driver 124 supplies the voltages necessary for data writing, reading, and erasing to the row decoder 112, the sense amplifier 113, and the source line SL. The row decoder 112 and the sense amplifier 113 transfer the voltages supplied from the driver 124 to the memory cell transistor MC.

The register 123 holds various signals. For example, the register 123 holds statuses of data write and erase operations, and thereby informs, for example, the external controller whether the operation has been normally completed. The register 123 is also capable of holding various tables.

The input/output (I/O) buffer 125 temporarily stores data input to and output from the external controller in data writing and reading.

Although the planar NAND flash memory in which the memory cell transistors are two-dimensionally arranged on the semiconductor substrate has been described above by way of example, the present embodiment is also applicable to a three-dimensionally stacked nonvolatile semiconductor memory in which memory cell transistors are three-dimensionally arranged on a semiconductor substrate.

The configuration of the memory cell array of the three-dimensionally stacked nonvolatile semiconductor memory is described in, for example, U.S. patent application Ser. No. 12/407,403, filed Mar. 19, 2009 “three-dimensionally stacked nonvolatile semiconductor memory”. The configuration is also described in, for example, U.S. patent application Ser. No. 12/406,524, filed Mar. 18, 2009 “three-dimensionally stacked nonvolatile semiconductor memory”, U.S. patent application Ser. No. 13/816,799, filed Sep. 22, 2011 “nonvolatile semiconductor memory device”, and U.S. patent application Ser. No. 12/532,030, filed Mar. 23, 2009 “semiconductor memory and manufacturing method of the same”. The entire contents of these patent applications are incorporated herein by reference.

[Data Storing Method by Sequential Storage]

The present embodiment uses a sequential storage method in which m memory cell transistors MC are treated as one unit (hereinafter referred to as a storage unit), and data are stored in the sequence of cell values stored in the memory cell transistors MC of the storage unit. It should be noted that m is a natural number equal to or more than 2 and less than or equal to n.

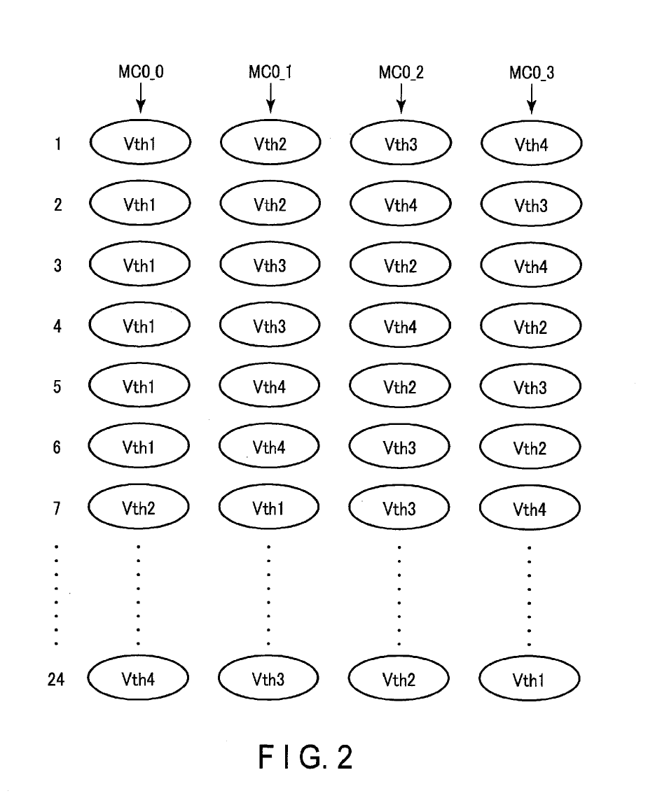

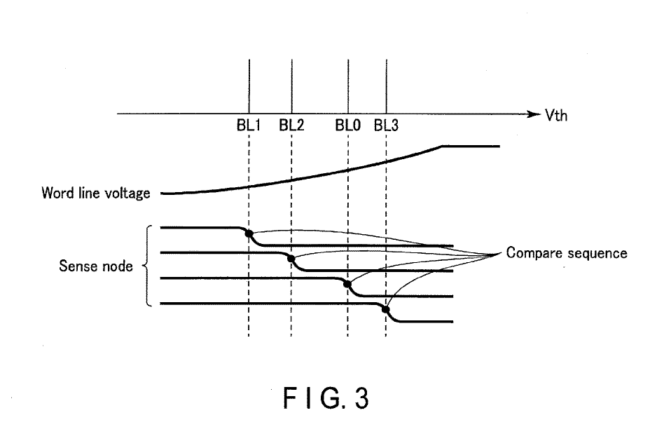

A data storing method by sequential storage is described with reference to FIGS. 2 and 3.

According to the embodiment, writing is performed so that each of the m memory cell transistors MC in the storage unit will have different threshold voltages Vth1, Vth2, . . . , and Vthm. The threshold voltages Vth1 to Vthm here do not need to be specific values or in a specific range, and have only to have different values. “Vth(m−1)<Vthm” is satisfied.

For example, when one of the m memory cell transistors MC has the threshold voltage Vth1, none of the other (m−1) memory cell transistors have the threshold voltage Vth1, and the other (m−1) memory cell transistors have other (m−1) threshold voltages. That is, only one of the m memory cell transistors MC has a threshold voltage Vthi (i=1 to m). As will be described later, the m memory cell transistors MC that constitute the storage unit can hold m! kinds of data patterns as a whole. The reason for the ml kinds is that the m! kinds can be represented by the total number of permutations that can be formed by extracting m kinds from different m kinds.

A specific data storing method is shown in FIG. 2. In the example shown in FIG. 2, m=4. For example, the memory cell transistor connected to the bit line BL0 is written as MC0_0. Similarly, the memory cell transistor connected to the bit line BL1 is written as MC0_1, the memory cell transistor connected to the bit line BL2 is written as MC0_2, and the memory cell transistor connected to the bit line BL3 is written as MC0_3. These memory cell transistors MC0_0, MC0_1, MC0_2, and MC0_3 are connected to the same word line WL0.

In the case shown, each of the four memory cell transistors MC0_0, MC0_1, MC0_2, and MC0_3 has one of the threshold voltages Vth1, Vth2, Vth3, and Vth4, and all of the memory cell transistors MC0_0, MC0_1, MC0_2, and MC0_3 have different threshold voltages. In this case, the four memory cell transistors MC0_0, MC0_1, MC0_2, and MC0_3 that constitute the storage unit can hold 4! (=24) kinds of data patterns as a whole.

In the example shown in FIG. 3, the threshold voltages are sensed from the memory cell transistor connected to each of the bit lines BL0 to BL3. The voltage of the word line connected in common to the four memory cell transistors connected to each of the bit lines BL0 to BL3 is increased gradually as shown in FIG. 3. Thus, the threshold voltage of each of the memory cell transistors is sensed in a sense node of the sense amplifier connected to each of the bit lines BL0 to BL3 in ascending order of the threshold voltages of the memory cell transistors. In the example shown in FIG. 3, the bit lines BL1, BL2, BL0, and BL3 are in the descending order of the threshold voltages of the memory cell transistors.

It is possible to judge data held by the m memory cell transistors MC that constitute the storage unit by comparing the magnitudes of the threshold voltages of the m memory cell transistors MC by the method shown in FIG. 3. According to this read method, data are judged by the comparison of the threshold voltages of the memory cell transistors MC. Thus, the magnitude relation of the threshold voltages of the memory cell transistors to be compared has only to be maintained, and the incidence of wrong reading can be considerably reduced as compared to a method in which data is read by comparing a reference voltage with the threshold voltage of the memory cell.

If the number of data holding states in this data storing method is found, the condition for the number of data holding states by sequential storage to be greater than the number of data holding states in the case where the memory cells are single-level cells (SLC) is “log₂(m!)>m”, and this condition is satisfied when m is equal to or more than 4. That is, if there are four or more memory cell transistors MC that constitute the storage unit, the data amount that can be stored is greater than when the memory cells are SLCs. The SLC is a memory cell capable of independently storing one bit of data.

[Configuration of Sense Amplifier]

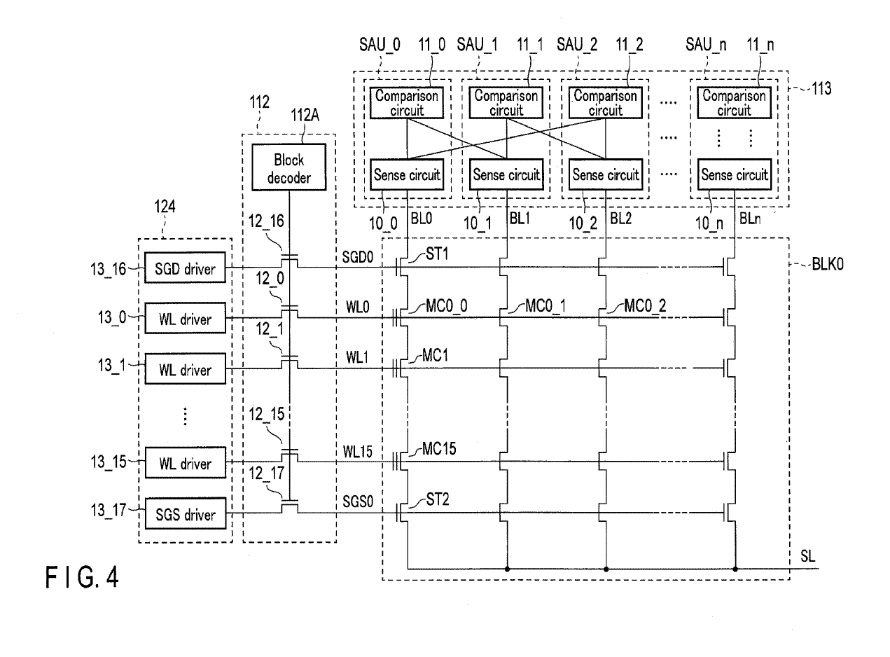

The configuration of the sense amplifier 113 according to the embodiment is described with reference to FIG. 4. As shown, the sense amplifier 113 includes the sense amplifier units SAU_0 to SAU_n. The sense amplifier unit SAU_0 is electrically connected to the bit line BL0. The sense amplifier unit SAU_1 is electrically connected to the bit line BL1, and the sense amplifier unit SAU_2 is electrically connected to the bit line BL2. Similarly, the sense amplifier unit SAU_n is electrically connected to the bit line BLn. A sense amplifier unit SAU when mentioned in this way hereinafter indicates each of the sense amplifier units SAU_0 to SAU_n.

The sense amplifier unit SAU_0 includes a sense circuit 10_0 and a sequential comparison circuit 11_0. The sense amplifier unit SAU_1 includes a sense circuit 10_1 and a sequential comparison circuit 11_1, and the sense amplifier unit SAU_2 includes a sense circuit 10_2 and a sequential comparison circuit 11_2. Similarly, the sense amplifier unit SAU_n includes a sense circuit 10_n and a sequential comparison circuit 11_n. A sense circuit 10 when mentioned in this way hereinafter indicates each of the sense circuits 10_0, 10_1, 10_2, . . . , and 10_n, and a sequential comparison circuit 11 when mentioned in this way hereinafter indicates each of the sequential comparison circuits 11_0, 11_1, 11_2, . . . , and 11_n.

Here, a configuration for reading data stored in three memory cell transistors MC0_0, MC0_1, and MC0_2 as the storage unit is described. The bit line BL0 is electrically connected to the sense circuit 10_0. The bit line BL1 is electrically connected to the sense circuit 10_1, and the bit line BL2 is electrically connected to the sense circuit 10_2. The output portion of the sense circuit 10_0 is electrically connected to each of the sequential comparison circuits 11_0 to 11_3. The output portion of the sense circuit 10_1 is electrically connected to each of the sequential comparison circuits 11_0 and 11_1. Moreover, the output portion of the sense circuit 10_2 is electrically connected to each of the sequential comparison circuits 11_1 and 11_2.

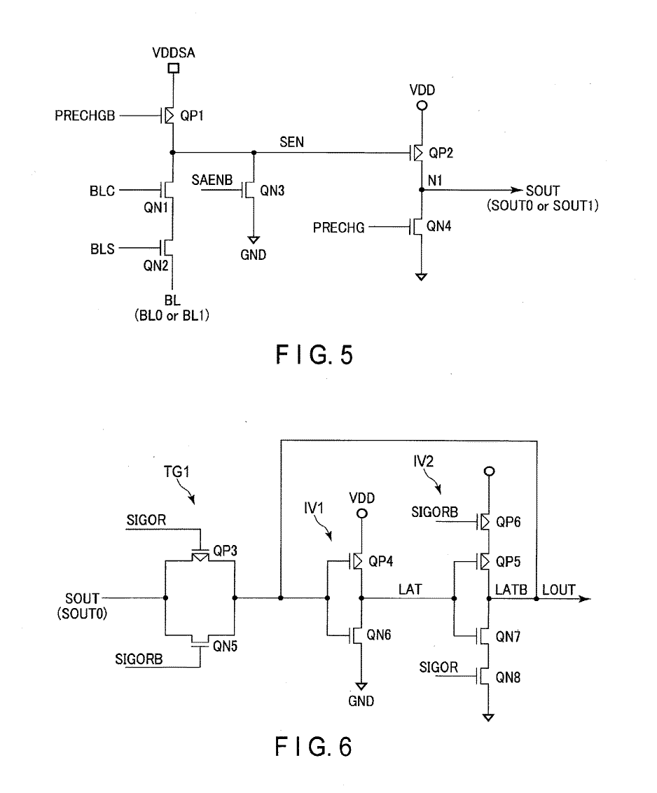

Next, the circuit configuration of the sense circuit 10 is described with reference to FIG. 5.

As shown in FIG. 5, the sense circuit 10 has p-channel MOS field effect transistors (hereinafter, pMOS transistors) QP1 and QP2, and n-channel MOS field effect transistors (hereinafter, nMOS transistors) QN1, QN2, QN3, and QN4.

The bit line BL is electrically connected to the source of the nMOS transistor QN2. The drain of the nMOS transistor QN2 is connected to the source of the nMOS transistor QN1. The drain of the nMOS transistor QN1 is connected to the drain of the pMOS transistor QP1, and also connected to the drain of the nMOS transistor QN3 and the gate of the pMOS transistor QP2. The drain of the pMOS transistor QP2 is connected to the drain of the nMOS transistor QN4. A signal SOUT is output to the sequential comparison circuit 11 from a node N1 between the drain of the pMOS transistor QP2 and the drain of the nMOS transistor QN4.

A power supply voltage VDDSA is supplied to the source of the pMOS transistor QP1. A reference voltage, for example, a ground potential GND (“L” level (0 V)) is supplied to the source of the nMOS transistor QN3. Moreover, a power supply voltage VDD (“H” level) is supplied to the source of the pMOS transistor QP2, and a ground potential GND is supplied to the source of the nMOS transistor QN4.

In FIG. 5, BL0 or BL1 is shown as the bit line connected to the sense circuit 10, and as its signal SOUT, SOUT0 or SOUT1 is shown. This is because the threshold voltages of the memory cell transistors MC0_0 and MC0_1 are compared in the read operation described later.

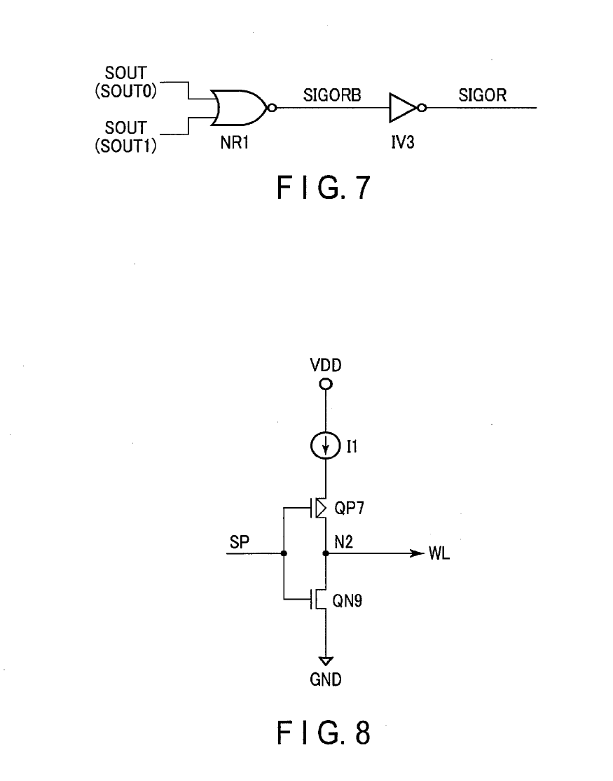

Next, the circuit configuration of the sequential comparison circuit 11 is described with reference to FIGS. 6 and 7.

The sequential comparison circuit 11 receives the signal SOUT from the sense circuit 10 shown in FIG. 5, and latches a signal corresponding to the signal SOUT.

As shown in FIG. 6, the sequential comparison circuit 11 has a transfer gate TG1, an inverter IV1, and a clocked inverter IV2. The transfer gate TG1 includes a pMOS transistor QP3 and an nMOS transistor QN5. The inverter IV1 includes a pMOS transistor QP4 and an nMOS transistor QN6. The clocked inverter IV2 includes pMOS transistors QP5 and QP6 and nMOS transistors QN7 and QN8.

The signal SOUT is input to one end of the transfer gate TG1 from the sense circuit 10. The other end of the transfer gate TG1 is connected to the input end of the inverter IV1. The output end (a node LAT) of the inverter IV1 is connected to the input end of the clocked inverter IV2. Moreover, the output end (a node LATE) of the clocked inverter IV2 is connected to the input end of the inverter IV1. A signal LOUT latched in the sequential comparison circuit 11 is output from the node LATE.

As shown in FIG. 7, the sequential comparison circuit 11 has a NOR circuit NR1 and an inverter IV3. One (e.g., SOUT0) of two signals SOUT to be compared is input to a first input terminal of the NOR circuit NR1, and the other (e.g., SOUT1) of the two signals SOUT is input to a second input terminal of the NOR circuit NR1. In the case shown here in which the cell currents of the bit lines BL0 and BL1 are compared, the signals SOUT0 and SOUT1 are input.

A signal SIGORB is output from the output terminal of the NOR circuit NR1, and input to the input terminal of the inverter IV3. A signal SIGOR is output from the inverter IV3. The signal SIGOR is supplied to the gates of the pMOS transistor QP3 and an nMOS transistor QN8. Further, the signal SIGORB is supplied to the gates of the nMOS transistor QN5 and the pMOS transistor QP6.

The sense amplifier unit SAU senses and compares the cell currents of two different memory cell transistors MC, and thereby latches data in accordance with which of the memory cell transistors has turned on first. That is, data is latched on the basis of the magnitude relation of the threshold voltages of the two memory cell transistors MC.

[Word Line Drivers]

In the present embodiment, the voltage of the selected word line is increased gradually in the read operation, that is, the voltage of the selected word line is swept, for example, from 0 V to a positive first voltage. The configurations of word line drivers and the row decoder 112 according to the embodiment are described with reference to FIG. 4.

The driver 124 has word line drivers 13_0, 13_1, . . . , and 13_15, and select gate line drivers 13_16 and 13_17. The row decoder 112 has nMOS transistors 12_0, 12_1, and 12_17, and a block decoder 112A.

Each of the word line drivers 13_0 to 13_15 supplies each of the nMOS transistors 12_0 to 12_5 of the row decoder 112 with voltages necessary for data writing, reading, and erasing that have been supplied from the charge pump 122. Each of the word line drivers 13_0 to 13_15 further has a driver to increase gradually a word line voltage shown in FIG. 8. The driver shown in FIG. 8 will be described later in detail.

Each of the select gate line drivers 13_16 and 13_17 supplies each of the nMOS transistors 12_16 and 12_17 of the row decoder 112 with necessary voltages supplied from the charge pump 122 in data writing, reading, and erasing.

The block decoder 112A outputs a signal which brings the nMOS transistors 12_0 to 12_17 of the row decoder 112 into a conducting state or a cutoff state in accordance with a block address. Specifically, in data writing, reading, and erasing, the block decoder 112A outputs a signal which brings the nMOS transistors 12_0 to 12_17 into a conducting state when an input block address corresponds to the block BLK0. In contrast, the block decoder 112A outputs a signal which brings the nMOS transistors 12_0 to 12_17 into a cutoff state when a block address does not correspond to the block BLK0.

The nMOS transistors 12_0 to 12_15 of the row decoder 112 come into the conducting state or the cutoff state in accordance with the signal output from the block decoder 112A, and transfer to the word lines WL0 to WL15 or cut off the voltages supplied from the word line drivers 13_0 to 13_15.

The nMOS transistors 12_16 and 12_17 of the row decoder 112 come into the conducting state or the cutoff state in accordance with the signal output from the block decoder 112A, and transfer to the select gate lines SGD0 and SGS0 or cut off the voltages supplied from the select gate line drivers 13_16 and 13_17.

Next, the driver for sweeping the voltage of the selected word line in the read operation is described with reference to FIG. 8.

The driver shown in FIG. 8 has a constant current source I1, a pMOS transistor QP7, and an nMOS transistor QN9. The output terminal of the constant current source I1 is connected to the source of the pMOS transistor QP7. The drain of the pMOS transistor QP7 is connected to the drain of the nMOS transistor QN9. A node N2 between the drain of the pMOS transistor QP7 and the drain of the nMOS transistor QN9 is connected to the word line WL via the row decoder 112. A power supply voltage VDD is supplied to the input terminal of the constant current source I1, and a ground potential GND is supplied to the source of the nMOS transistor QN9. A signal SP for controlling the increase of the word line voltage in response to an instruction from the controller 121 is input to the gates of the pMOS transistor QP7 and the nMOS transistor QN9. As a result, a current for increasing the word line voltage is supplied to the word line WL from the node N2 via the row decoder 112.

[Read Operation]

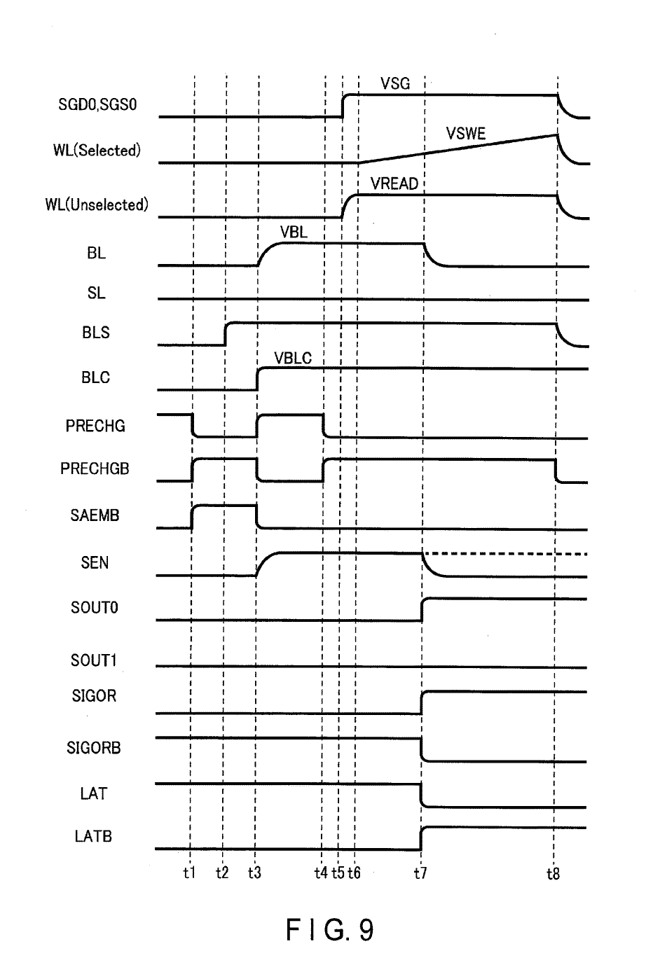

Next, the read operation according to the present embodiment is described with reference to FIG. 9.

A timing chart of various control signals and potentials at various nodes in the read operation is shown in FIG. 9. In the case described here, data is read from the magnitude relation of the threshold voltages of the memory cell transistors MC0_0 and MC0_1. The memory cell transistors MC0_0 and MC0_1 are connected to the same word line WL0. The memory cell transistor MC0_0 is electrically connected to the bit line BL0. The memory cell transistor MC0_1 is electrically connected to BL1.

First, the sense circuit 10 discharges a sense node SEN. Specifically, the controller 121 brings a signal PRECHGB to an “H (high)” level, brings a signal BLC and a signal BLS to an “L (low)” level, and brings a signal SAENB to an “H” level (time t1). Thus, the sense circuit 10 discharges the sense node SEN via the nMOS transistor QN3. The node LATB is reset, and brought to an “L” level.

The controller 121 then brings the signal BLS to an “H” level to connect the sense amplifier unit SAU to the corresponding bit line BL (time t2). Specifically, the sense amplifier unit SAU_0 is connected to the corresponding bit line BL0, and the sense amplifier unit SAU_1 is connected to the corresponding bit line BL1.

The sense circuit 10 then precharges the bit line BL and the sense node SEN. Specifically, the controller 121 brings the signal SAENB to an “L” level, brings the signal BLC to an “H” level, and brings the signal PRECHGB to an “L” level (e.g., time t3). Thus, the sense circuit 10 precharges the bit lines BL0 and BL1 via the nMOS transistors QN1 and QN2. The sense circuit 10 also precharges the sense node SEN. A voltage VBLC in the drawing is a voltage which determines a bit line voltage, and the bit line voltage becomes a voltage VBL clamped by the voltage VBLC.

The sense circuit 10 then senses the bit line BL. Specifically, the controller 121 brings the signal PRECHGB to an “H” level (time t4). The select gate line driver 13_16 then applies a voltage VSG to the select gate line SGD0, and the select gate line driver 13_17 applies a voltage VSG to the select gate line SGS0. Thus, the controller 121 brings the select transistors ST1 and ST2 into the conducting state. The voltage VSG is a voltage which fully turns on the select transistors regardless of the source-side potentials of the select transistors ST1 and ST2. Further, the word line drivers 13_1 to 13_15 apply a voltage VREAD to the unselected word lines WL1 to WL15 (time t5). Further, the word line driver 130 applies, to the selected word line WL0, a voltage VSWE which is increased gradually, for example, from 0 V to the positive first voltage (times t6 to t8). That is, the voltage VSWE of the selected word line WL0 is swept from 0 V to the first voltage by the word line driver 13_0. The voltage of the source line SL is, for example, 0 V.

When the voltage VSWE of the selected word line WL0 is swept, the memory cell transistor having a lower threshold voltage between the memory cell transistors MC0_0 and MC0_1 connected to the word line WL0 first turns on, and a cell current runs through the memory cell transistor which has turned on. In the case described here, the memory cell transistor MC0_0 first turns on. That is, the threshold voltage of the memory cell transistor MC0_0 is lower than the threshold voltage of the memory cell transistor MC0_1.

If the memory cell transistor MC0_0 turns on at a time t7, a cell current runs to the source line SL from the sense node SEN, and the potential of the sense node SEN decreases. On the other hand, the memory cell transistor MC0_1 is off at the time t7, so that no current runs to the source line SL from the sense node SEN, and the potential of the sense node SEN substantially maintains VDDSA.

In the sense circuit 10_0 which senses the bit line BL0, if the potential of the sense node SEN decreases to 0 V at the time t7, the pMOS transistor QP2 turns on. Thus, the sense circuit 10_0 outputs the voltage VDD (“H” level) as the signal SOUT0. On the other hand, in the sense circuit 10_1 which senses the bit line BL1, the potential of the sense node SEN substantially maintains VDDSA at the time t7, so that the pMOS transistor QP2 remains off. Thus, the sense circuit 10_1 outputs the “L” level as the signal SOUT1.

The signal SOUT0 (“H” level) and the signal SOUT1 (“L” level) are input to the sequential comparison circuit 11. The signal SOUT0 is input to the input terminal of the transfer gate TG1 and the first input terminal of the NOR circuit NR1. The signal SOUT1 is input to the second input terminal of the NOR circuit NR1.

The signal SOUT0 (“H” level) input to the transfer gate TG1 passes through the inverter IV1 and becomes the “L” level at the node LAT. Further, the signal SOUT0 passes through the clocked inverter IV2 and becomes the “H” level at the node LATB. In this instance, the signal SIGORB output from the output terminal of the NOR circuit NR1 is at the “L” level. Moreover, the signal SIGOR output from the inverter IV3 is at the “H” level. Thus, if the signal SOUT0 (“H” level) is input to the transfer gate TG1, the transfer gate TG1 immediately comes into the cutoff state. The clocked inverter IV2 is activated, so that the “H” level is latched in the node LATB, and the “L” level is latched in the node LAT.

While the magnitude relation of the threshold voltages of the memory cell transistor MC0_0 and the memory cell transistor MC0_1 is compared in the case of the operation described above, the magnitude relation of the threshold voltages of the memory cell transistor MC0_1 and the memory cell transistor MC0_2 and the magnitude relation of the threshold voltages of the memory cell transistor MC0_2 and the memory cell transistor MC0_0 can also be compared by similar operations.

The signal LOUT latched in the nodes LATB of the sequential comparison circuits 11_0 to 11_2 is then output to the controller 121. The controller 121 finds the magnitude relation of the threshold voltages of the memory cell transistors MC0_0, MC0_1, and MC0_2 from the received signal LOUT. How to find this magnitude relation of the threshold voltages will be described later. Further, data on the found magnitude relation is output to the encoder 121B of the controller 121. The encoder 121B encodes the data on the magnitude relation into binary data. The signal encoded by the encoder 121E is output to the external controller via the input/output buffer 125.

[How to Find Magnitude Relation of Threshold Voltages]

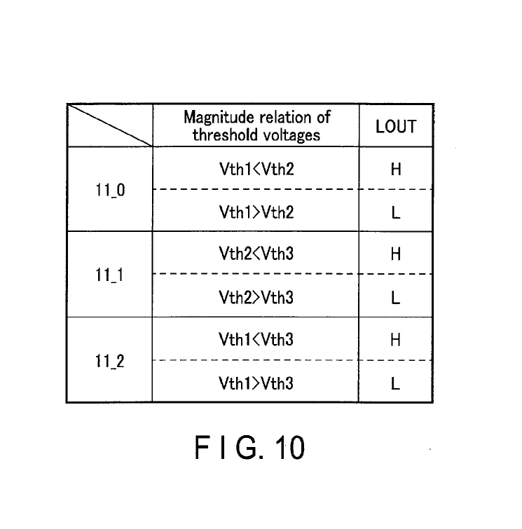

The magnitude relation of the threshold voltages of the memory cell transistors, and the signal LOUT output from the sequential comparison circuit are shown in FIG. 10. As described above, the threshold voltages of the memory cell transistors MC0_0, MC0_1, and MC0_2 are represented by Vth1, Vth2, and Vth3, respectively.

As shown in FIG. 10, when the threshold voltage Vth1 is lower than the threshold voltage Vth2, the signal LOUT output from the sequential comparison circuit 11_0 is “H”. When the threshold voltage Vth1 is higher than the threshold voltage Vth2, the signal LOUT from the sequential comparison circuit 11_0 is “L”. Similarly, when the threshold voltage Vth2 is lower than the threshold voltage Vth3, the signal LOUT from the sequential comparison circuit 11_1 is “H”. When the threshold voltage Vth2 is higher than the threshold voltage Vth3, the signal LOUT from the sequential comparison circuit 11_1 is “L”. When the threshold voltage Vth1 is lower than the threshold voltage Vth3, the signal LOUT from the sequential comparison circuit 11_2 is “H”. When the threshold voltage Vth1 is higher than the threshold voltage Vth3, the signal LOUT from the sequential comparison circuit 11_2 is “L”.

Here, for example, when the outputs of the sequential comparison circuits 11_0, 11_1, and 11_2 are respectively “H”, “H”, and “H”, the magnitude relation of the threshold voltages can be found as follows. The signal LOUT from the sequential comparison circuit 11_0 is “H”, so that vth1<Vth2 is known. The signal LOUT from the sequential comparison circuit 11_1 is “H”, so that Vth2<Vth3 is known. Therefore, the magnitude relation of the threshold voltages can be judged to be Vth1<Vth2<Vth3. In this case, the signal LOUT from the sequential comparison circuit 11_2 is always “H”.

When the outputs of the sequential comparison circuits 11_0, 11_1, and 11_2 are respectively “L”, “L”, and “L”, the magnitude relation of the threshold voltages can be found as follows. The signal LOUT from the sequential comparison circuit 11_0 is “L”, so that Vth1>Vth2 is known. The signal LOUT from the sequential comparison circuit 11_1 is “L”, so that Vth2>Vth3 is known. Therefore, the magnitude relation of the threshold voltages can be judged to be Vth1>Vth2>Vth3. In this case, the signal LOUT from the sequential comparison circuit 11_2 is always “L”.

When the outputs of the sequential comparison circuits 11_0, 11_1, and 11_2 are respectively “H”, “L”, and “H”, the magnitude relation of the threshold voltages can be found as follows. The signal LOUT from the sequential comparison circuit 11_0 is “H”, so that Vth1<Vth2 is known. The signal LOUT from the sequential comparison circuit 11_1 is “L”, so that Vth2>Vth3 is known. Therefore, (Vth1 or Vth3)<Vth2 is known. The signal LOUT from the sequential comparison circuit 11_2 is “H”, so that Vth1<Vth3 is known. Therefore, the magnitude relation of the threshold voltages can be judged to be Vth1<Vth3<Vth2.

As described above, the magnitude relation of the threshold voltages Vth1, Vth2, and Vth3 can be found from the outputs of the sequential comparison circuits 11_0, 11_1, and 11_2. Although the magnitude relation of the threshold voltages Vth1, Vth2, and Vth3 of the three memory cell transistors MC0_0, MC0_1, and MC0_2 is found in the case shown here, the magnitude relation of four threshold voltages can also be found from the outputs of six sequential comparison circuits when the number of memory cell transistors is four. That is, when the number of memory cell transistors is m, the magnitude relation of m threshold voltages can also be found from the outputs of (m(m−1)/2) sequential comparison circuits. That is, (m−1)/2 sequential comparison circuits are needed for one bit line when one cell can hold LOG₂(m!)/m bits of data.

### Effects of Embodiment

According to the present embodiment, it is possible to provide a semiconductor memory device capable of accurately reading data by use of a sequential storage method of storing data by the sequence of cell values stored in memory cells.

The advantageous effects of the data storing method and reading method according to the embodiment are described below in detail.

According to the embodiment, data are read by the magnitude relation of the threshold voltages of two memory cells to be compared, so that it is not necessary to have a reference voltage for judging the threshold voltages, and it is possible to reduce the influence of the variation of the threshold voltages attributed to, for example, a write disturb, a read disturb, or a temperature change. Thus, accurate data reading is possible. On the other hand, in the case of a device which uses a reference voltage to judge the threshold voltages of memory cells, it is necessary to provide an adequate margin between the threshold voltage and the reference voltage if the variation of the threshold voltages attributed to, for example, a write disturb, a read disturb, or a temperature change is taken into consideration. However, providing an adequate margin is often extremely difficult, in which case wrong reading may occur if the threshold voltages of memory cells vary. According to the present embodiment, the reference voltage for judging the threshold voltages is not used, and the threshold voltages of two memory cells are compared to make a judgment, so that the variation of the threshold voltages is offset, and the effect of the variation of the threshold voltages on reading can be reduced.

According to the embodiment, the effect of a potential rise of the source line SL caused by the cell current on the cell current can be reduced. Even in this embodiment, the potential of the source line SL floats, and the cell current decreases. However, the cell currents of two memory cells to be compared also decrease, and no misjudgment is therefore made.

According to the embodiment, the voltage of the selected word line has only to be increased gradually from 0 V to the first voltage during the read operation, so that it is not necessary to raise the voltage of the word line and wait for the voltage to stabilize. In this way, the reading speed can be higher. On the other hand, in the case of a device which uses the reference voltage to judge the threshold voltages, the memory cells are read by a voltage close to the threshold voltages of the memory cells, so that it is necessary to raise the voltage of the word line and wait for the word line voltage to stabilize, and perform reading with the stabilized word line voltage. This has an effect on the reading speed. When the memory cells are multi-level cells (MLC), it is necessary to set the word line voltage to more than one voltage to perform reading; for example, reading is perform by setting the word line voltage to a first read voltage, and then reading is perform by setting the word line voltage to a second read voltage. According to the present embodiment, as described above, reading can be perform by (linearly) increasing gradually the voltage of the word line from 0 V to a certain voltage only once. Thus, the reading speed can be higher. The MLC is a memory cell capable of storing two-bit data.

According to the embodiment, after the start of the sensing of the cell currents running through the bit lines BL, the sensing is finished at the point where one of the two memory cells to be compared has turned on, and data is latched in the sense amplifier. Thus, there is no need for a strobe signal that indicates the timing of latching the data. On the other hand, in the case of a device which uses the reference voltage to judge the threshold voltages, a strobe signal that indicates the timing of latching the data in the sense amplifier is needed.

As described above, the present embodiment provides a semiconductor memory device which uses a sequential storage method of storing data by the sequence of cell values stored in memory cells, so that accurate data reading is possible without wrong reading.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first memory cell having a first threshold voltage;
a second memory cell having a second threshold voltage;
a word line which is electrically connected to the first and second memory cells;
a first bit line which is electrically connected to the first memory cell;
a second bit line which is electrically connected to the second memory cell;
a sense amplifier which is electrically connected to the first bit line and the second bit line and which senses the first threshold voltage and the second threshold voltage; and
a driver which increases gradually the voltage of the word line,
wherein when the voltage of the word line is increased gradually by the driver, the sense amplifier senses the first and second threshold voltages in ascending order.

2. The semiconductor memory device according to claim 1,
wherein the sense amplifier has a latch circuit which latches a first voltage when the first threshold voltage is lower than the second threshold voltage and which latches a second voltage when the first threshold voltage is higher than the second threshold voltage.

3. The semiconductor memory device according to claim 2, further comprising:
a controller which judges the magnitude relation of the first and second threshold voltages on the basis of the voltage latched in the latch circuit.

4. The semiconductor memory device according to claim 3, further comprising:
an arithmetic circuit which encodes the judgment result of the magnitude relation of the first threshold voltage and the second threshold voltage.

5. The semiconductor memory device according to claim 1, further comprising:
a third memory cell which has a third threshold voltage and which is electrically connected to the word line; and
a third bit line which is electrically connected to the third memory cell,
wherein the sense amplifier is electrically connected to the third bit line, and the sense amplifier senses the first, second, and third threshold voltages in ascending order when the voltage of the word line is increased gradually by the driver.

6. The semiconductor memory device according to claim 5,
wherein the sense amplifier comprises
a first latch circuit which latches a first voltage when the first threshold voltage is lower than the second threshold voltage and which latches a second voltage when the first threshold voltage is higher than the second threshold voltage,
a second latch circuit which latches the first voltage when the second threshold voltage is lower than the third threshold voltage and which latches the second voltage when the second threshold voltage is higher than the third threshold voltage, and
a third latch circuit which latches the first voltage when the first threshold voltage is lower than the third threshold voltage and which latches the second voltage when the first threshold voltage is higher than the third threshold voltage.

7. The semiconductor memory device according to claim 6, further comprising:
a controller which judges the magnitude relation of the first, second, and third threshold voltages on the basis of the voltages latched in the first, second, and third latch circuits.

8. The semiconductor memory device according to claim 7, further comprising:
an arithmetic circuit which encodes the judgment result of the magnitude relation of the first, second, and third threshold voltages.

9. The semiconductor memory device according to claim 1,
wherein each of the first and second memory cells has a stack gate which includes a control gate and a charge storage layer.

10. The semiconductor memory device according to claim 9, comprising a NAND flash memory.
